(19) United States
(12) Patent Application Publication
(10) Pub. No.: US 2014/0061891 A1
(43) Pub. Date: Mar. 6, 2014

(54) SEMICONDUCTOR CHIP PACKAGE AND MANUFACTURING METHOD THEREOF

(71) Applicant: SAMSUNG ELECTRO-MECHANICS CO., LTD., Suwon (KR)

(72) Inventors: Po Chul KIM, Suwon (KR); Kyung Ho Lee, Suwon (KR); Seung Wan Woo, Suwon (KR); Young Nam Hwang, Suwon (KR); Suk Jin Ham, Suwon (KR)

(73) Assignee: Samsung Electro-Mechanics Co., Ltd., Suwon (KR)

(21) Appl. No.: 13/800,662

(22) Filed: Mar. 13, 2013

(30) Foreign Application Priority Data
Sep. 4, 2012 (KR) 10-2012-0097616

(51) Int. Cl. H01L 23/00; H01L 21/56

(52) U.S. Cl. CPC H01L 23/562; H01L 21/56
USPC 257/704; 438/126

(57) ABSTRACT

Disclosed herein are a semiconductor chip package and a manufacturing method thereof. The manufacturing method of the semiconductor chip package includes: a) mounting a semiconductor chip on a printed circuit board (PCB); b) inserting a warpage suppressing reinforcement member into an inner ceiling of a mold manufactured in order to package the PCB having the semiconductor chip mounted thereon; c) combining the mold having the warpage suppressing reinforcement member inserted into the ceiling thereof with the upper surface of the PCB so as to surround the PCB having the semiconductor chip mounted thereon; d) injection-molding and filling a molding material in the mold, and hardening the molding material by applying heat, and e) hardening the molding material and then removing the mold to complete the semiconductor chip package.

### CROSS REFERENCE(S) TO RELATED APPLICATIONS

This application claims the benefit under 35 U.S.C. Section 119 of Korean Patent Application Serial No. 10-2012-0097616, entitled “Semiconductor Chip Package and Manufacturing Method Thereof” filed on September 4, 2012, which is hereby incorporated by reference in its entirety into this application.

### BACKGROUND OF THE INVENTION

1. Technical Field

The present invention relates to a semiconductor chip package and a manufacturing method thereof, and more particularly, to a semiconductor chip package and a manufacturing method thereof capable of suppressing warpage in the package generated due to difference in a thermal expansion coefficient among a printed circuit board (PCB), a semiconductor chip, and a molding material (an epoxy molding compound: EMC) at the time of molding the semiconductor chip.

2.Description of the Related Art

As a memory of an electronic portable device has gradually increased in capacitance, a semiconductor chip in a semiconductor package mounted in the electronic portable device has also become highly integrated. Therefore, a size of the semiconductor chip becomes larger. On the other hand, as the electronic portable device has a small size, a semiconductor chip package manufactured by mounting the semiconductor chip on a package substrate has been minimized, thinned, and lightened.

Meanwhile, the semiconductor chip package as described above is generally molded by a resin, or the like, to thereby be protected from an external environment. An epoxy molding compound (EMC), which is a material protecting the semiconductor chip from the external environment, is used to protect the semiconductor chip from the external environment such as moisture, shock, heat, or the like. As an EMC material, a thermosetting resin such as epoxy is generally used.

FIGS. 1A to 1C are views showing a manufacturing process of a semiconductor chip package of the related art.

As shown in FIG. 1A, in the manufacturing process of the semiconductor chip package of the related art, the semiconductor chip 102 is bonded to a printed circuit board (PCB) 101, and the PCB 101 and the semiconductor chip 102 are then entirely surrounded with a mold 103.

Next, as shown in FIG. 1B, in order to protect the semiconductor chip 102, the molding material (EMC) 104 is injection-molded in the mold 103, and hardened by applying heat.

Thereafter, as shown in FIG. 1C, the semiconductor chip package is completed by removing the mold 103.

However, during the processes of injection-molding the molding material 104 in the mold 103, and hardening the molding material 104 by applying the heat in order to protect the semiconductor chip 102 in the manufacturing process of the semiconductor chip package of the related art as described above, warpage may be generated in the package due to a difference in a thermal expansion coefficient among the PCB 101, the semiconductor chip 102, and the molding material 104.

### RELATED ART DOCUMENT

### Patent Document

(Patent Document 1) Korean Patent Laid-Open Publication No. KR 10-2004-0008080

(Patent Document 2) Korean Patent Laid-Open Publication No. KR 10-2007-0083021

### SUMMARY OF THE INVENTION

An object of the present invention is to provide a semiconductor chip package and a manufacturing method thereof capable of suppressing warpage in the package generated due to difference in a thermal expansion coefficient among the printed circuit board (PCB), a semiconductor chip, and a molding material (an epoxy molding compound: EMC) at the time of molding the semiconductor chip.

According to a first exemplary embodiment of the present invention, there is provided a semiconductor chip package including: a printed circuit board (PCB) forming a base of the package; a semiconductor chip mounted on the PCB; a molding part molding the entire upper surface of the PCB including the semiconductor chip to protect the semiconductor chip from external environment; and a warpage suppressing reinforcement member bonded to an upper surface of the molding part and suppressing warpage of the package generated due to a difference in a thermal expansion coefficient among the PCB, the semiconductor chip, and a molding material at the time of hardening the molding material of the molding part.

The molding material of the molding part may be a thermosetting resin.

The thermosetting resin may be any one of an epoxy resin, a phenol resin, a urea resin, a melamine resin, an unsaturated polyester resin, a polyurethane resin, and a polyimide resin.

The warpage suppressing reinforcement member may be made of a material having high rigidity and a low thermal expansion coefficient.

The warpage suppressing reinforcement member may be made of a carbon fiber composite material or a metal material.

The warpage suppressing reinforcement member may have any one of a sheet shape, a cross shape, and a net (lattice) shape.

According to a second exemplary embodiment of the present invention, there is provided a manufacturing method of a semiconductor chip package, the manufacturing method including: a) mounting a semiconductor chip on a printed circuit board (PCB); b) inserting a warpage suppressing reinforcement member into an inner ceiling of a mold manufactured in order to package the PCB having the semiconductor chip mounted thereon; c) combining the mold having the warpage suppressing reinforcement member inserted into the ceiling thereof with the upper surface of the PCB so as to surround the PCB having the semiconductor chip mounted thereon; d) injection-molding and filling a molding material in the mold and hardening the molding material by applying heat, and e) hardening the molding material and then removing the mold to complete the semiconductor chip package.

In step b), the warpage suppressing reinforcement member may be made of a material having high rigidity and a low thermal expansion coefficient.

The warpage suppressing reinforcement member may be made of a carbon fiber composite material or a metal material.

The warpage suppressing reinforcement member may have any one of a sheet shape, a cross shape, and a net (lattice) shape.

In step c), the molding material may be a thermosetting resin.

The thermosetting resin may be any one of an epoxy resin, a phenol resin, a urea resin, a melamine resin, an unsaturated polyester resin, a polyurethane resin, and a polyimide resin.

### BRIEF DESCRIPTION OF THE DRAWINGS

FIGS. 1A to 1C are views showing a manufacturing process of a semiconductor chip package of the related art;

FIG. 2 is a view showing a structure of a semiconductor chip package according to a preferred embodiment of the present invention;

FIG. 3 is a flow chart showing a performing process of a manufacturing method of a semiconductor chip package according to the preferred embodiment of the present invention;

FIGS. 4A to 4E are views sequentially showing a manufacturing process of the semiconductor chip package according to the manufacturing method of the semiconductor chip package according to the preferred embodiment of the present invention;

FIGS. 5A-5C are views showing various shapes of warpage suppressing reinforcement members of the semiconductor chip package according to the preferred embodiment of the present invention; and

FIGS. 6A and 6B are views showing each of the results obtained by measuring the differences in the warpage of semiconductor chip packages manufactured by a method of the related art and a method of the present invention, respectively.

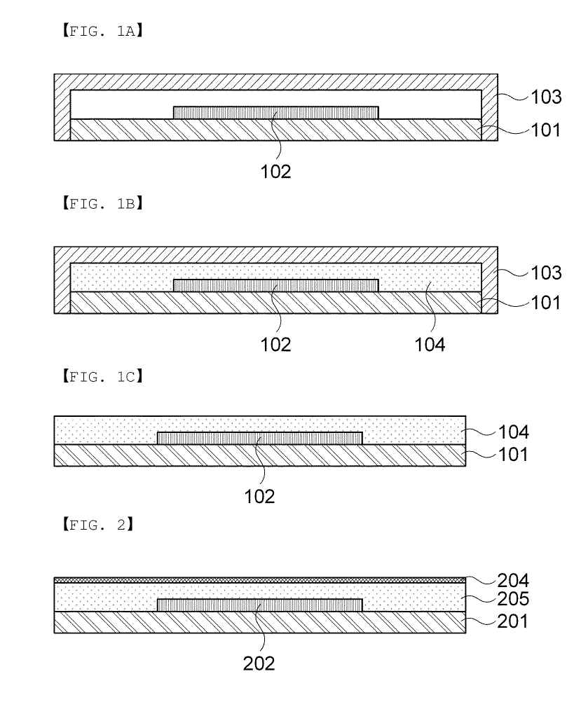

### DESCRIPTION OF THE PREFERRED EMBODIMENTS

Terms or words used in the specification and the appended claims are not construed to be limited to a dictionary definition but are to be construed as meanings and concepts meeting the technical details of the present invention based on the principle that the concept of the term can be properly defined in order to describe the present invention by the best way.

In addition, unless explicitly described to the contrary, the word “comprise” and variations such as “comprises” or “comprising”, will be understood to imply the inclusion of stated elements but not the exclusion of any other elements. In addition, the terms “-er”, “-or”, “module”, and “device” described in the specification mean units for processing at least one function and operation, and can be implemented by hardware components or software components and combinations thereof.

Hereinafter, embodiments of the present invention will be described in detail with reference to the accompanying drawings.

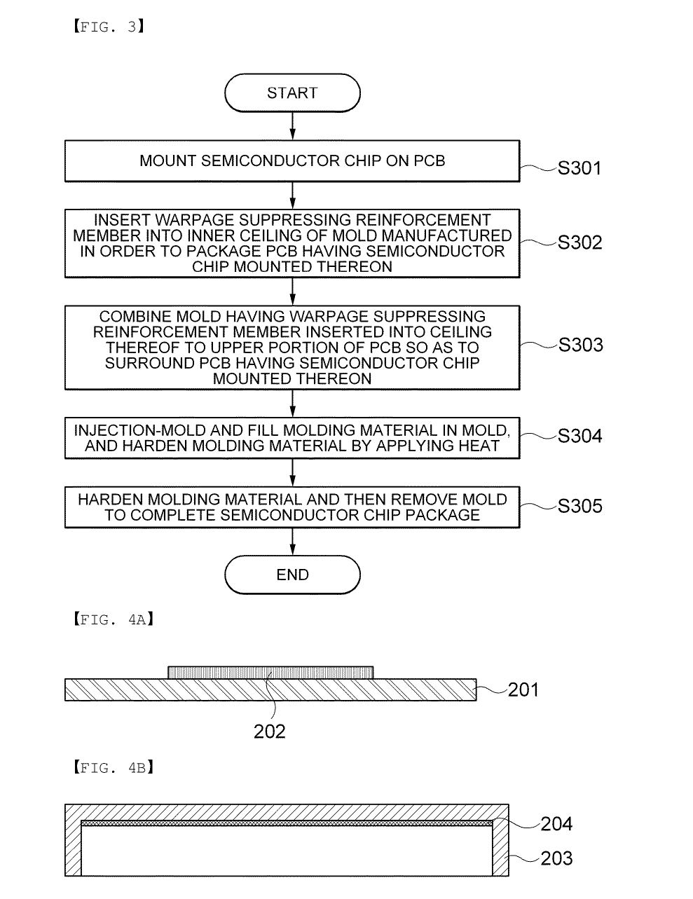

FIG. 2 is a view showing a structure of a semiconductor chip package according to a preferred embodiment of the present invention.

Referring to FIG. 2, the semiconductor chip package according to the preferred embodiment of the present invention includes a printed circuit board (PCB) 201, a semiconductor chip 202, a molding part 205, and a warpage suppressing reinforcement member 204.

The PCB 201 forms a base of the package. Here, the PCB 201 may be consisted in a single layer and a multilayer formed by multilayering various layers.

The semiconductor chip 202 is mounted on the PCB 201. Here, the semiconductor chip 202 is electrically connected to a lead finger (not shown) by a bond wire (not shown), or a bonding pad (not shown) of the semiconductor chip 202 and bonded to a wire bonding conductive pattern (not shown) of the PCB 201 by a wire.

The molding part 205 molds the entire upper surface of the PCB 201 including the semiconductor chip 202 to thereby protect the semiconductor chip 202 from an external environment. Here, as a molding material of the molding part 205, a thermosetting resin may be used. Here, the thermosetting resin may include an epoxy resin, a phenol resin, a urea resin, a melamine resin, an unsaturated polyester resin, a polyurethane resin, a polyimide resin, or the like.

The warpage suppressing reinforcement member 204 is bonded to an upper surface of the molding part 205 and suppresses warpage of the package generated due to a difference in a thermal expansion coefficient among the PCB 201, the semiconductor chip 202, and the molding material at the time of hardening the molding material of the molding part 205. Here, the warpage suppressing reinforcement member 204 may be made of a material having high rigidity and a low thermal expansion coefficient.

Here, as the warpage suppressing reinforcement member 204, a carbon fiber composite material, a metal material, or the like may be used.

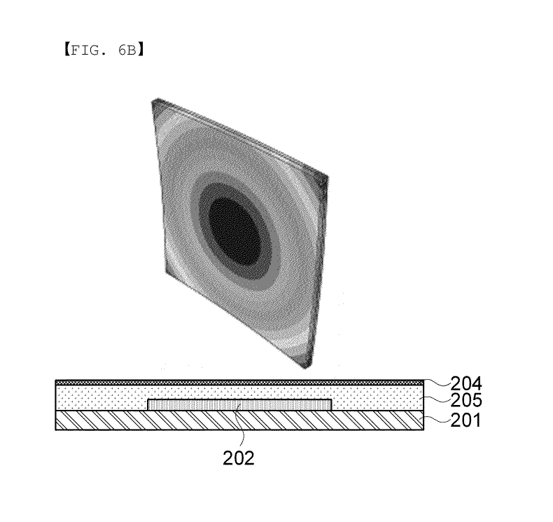

In addition, the warpage suppressing reinforcement member 204 may have various shapes such as a sheet shape shown in (a) of FIG. 5, a cross shape shown in (b) of FIG. 5, and a net (lattice) shape shown in (c) of FIG. 5.

Hereinafter, a manufacturing method of a semiconductor chip package according to the present invention having the above-mentioned configuration will be described.

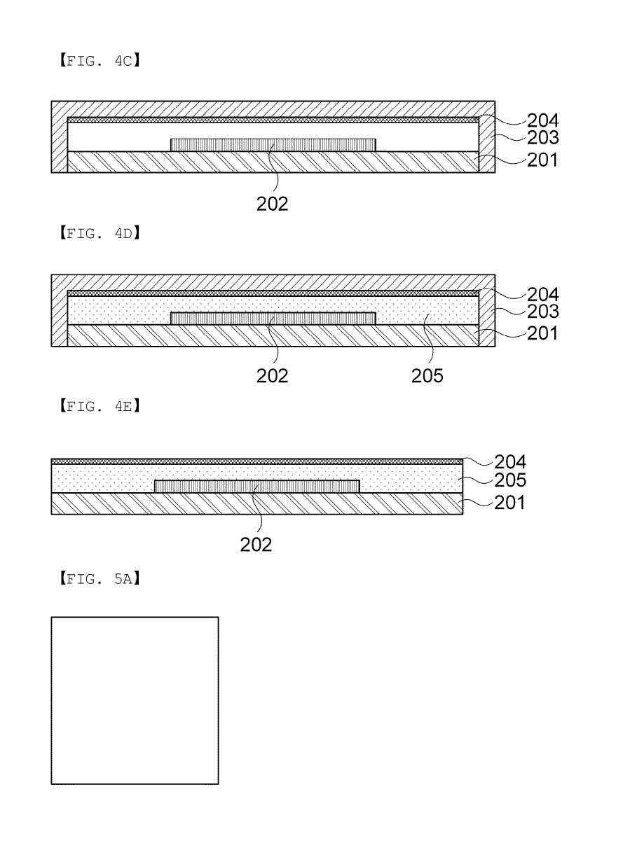

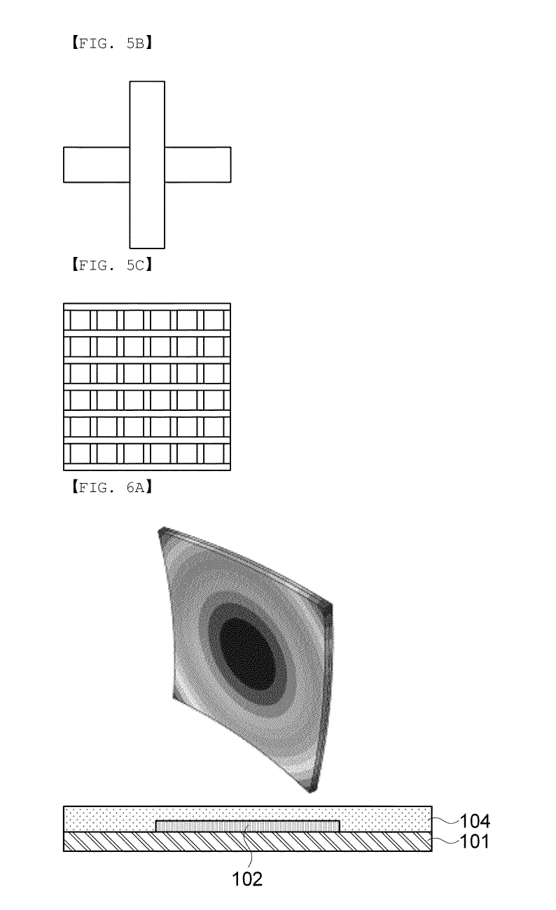

FIG. 3 is a flow chart showing a process of a manufacturing method of a semiconductor chip package according to the preferred embodiment of the present invention; and FIGS. 4A to 4E are views sequentially showing a manufacturing process of the semiconductor chip package according to the manufacturing method of the semiconductor chip package according to the preferred embodiment of the present invention.

Referring to FIGS. 3, and 4A to 4E, according to the manufacturing method of the semiconductor chip package according to the present invention, the semiconductor chip 202 is first mounted on the PCB 201 (S301). Here, as described above, the semiconductor chip 202 is electrically connected to a lead finger (not shown) by a bond wire (not shown), or a bonding pad (not shown) of the semiconductor chip 202 is bonded to a wire bonding conductive pattern (not shown) of the PCB 201 by a wire.

In addition, the warpage suppressing reinforcement member 204 is inserted into an inner ceiling of a mold 203 manufactured in order to package the PCB 201 having the semiconductor chip 202 mounted thereon (S302).

Here, the performing order of steps S301 and S302 is not necessarily limited thereto, and in some cases, step 5302 may be firstly performed before step 5301, and steps S301 and S302 may be simultaneously performed.

In addition, the warpage suppressing reinforcement member 204 may be made of a material having high rigidity and a low thermal expansion coefficient as described above. The material results in suppressing the warpage of the package generated due to a difference in a thermal expansion coefficient among the PCB 201, the semiconductor chip 202, and the molding material 205 at the time of hardening the molding material 205 to be described below.

Here, as the warpage suppressing reinforcement member 204, a carbon fiber composite material, a metal material, or the like may be used.

In addition, the warpage suppressing reinforcement member 204 may have various shapes such as a sheet shape shown in (a) of FIG. 5, a cross shape shown in (b) of FIG. 5, and a net (lattice) shape shown in (c) of FIG. 5, as described above.

Meanwhile, as described above, the mounting of the semiconductor chip 202 into the upper surface of the PCB 201 and inserting of the warpage suppressing reinforcement member 204 into the mold 203 are completed, the mold 203 having the warpage suppressing reinforcement member 204 inserted into the ceiling thereof is combined with the upper surface of the PCB 201 so as to surround the PCB 201 having the semiconductor chip 202 mounted thereon (S303). (see FIG. 4C).

Then, the injection-molding and filling a molding material 205 in the mold 203, and hardening the molding material 205 by applying heat are performed (S304). Here, as the molding material of the molding part 205, a thermosetting resin may be used.

Here, the thermosetting resin may include an epoxy resin, a phenol resin, a urea resin, a melamine resin, an unsaturated polyester resin, a polyurethane resin, a polyimide resin, or the like.

As described above, when the hardening of the molding material 205 is completed, the mold 203 is removed to finally complete the semiconductor chip package as shown in FIG. 4E (S305).

Meanwhile, FIGS. 6A and 6B are views showing each of results obtained by measuring the various warpage of the semiconductor chip packages manufactured by a method of the related art and a method of the present invention, respectively.

FIG. 6A shows a result obtained by measuring a warpage of a semiconductor chip package manufactured by a method of the related art, an extent (a height at which an edge portion of the semiconductor chip package is upwardly curled from a bottom thereof) of the warpage being measured in 122 μm.

FIG. 6B shows a result obtained by measuring a warpage of a semiconductor chip package (in the case of using a carbon fiber composite material made of the warpage suppressing reinforcement member 204) manufactured by a method of the present invention, an extent (a height at which an edge portion of the semiconductor chip package is upwardly curled from a bottom thereof) of the warpage being measured in 55 μm.

As appreciated by the above-described results, in the case of the semiconductor chip package manufactured by using the warpage suppressing reinforcement member according to the manufacturing method of present invention, the extent of the warpage was largely decreased as compared to the case of the semiconductor chip package manufactured by the manufacturing method of the related art.

According to the preferred embodiments of the present invention, the molding material is injection-molded and hardened in the mold in the state in which the warpage suppressing reinforcement member is inserted into the mold for molding the semiconductor chip to integrally stick the warpage suppressing reinforcement member and the molding material to each other, thereby capable of significantly suppressing the warpage in the package generated due to the difference in the thermal expansion coefficient among the printed circuit board (PCB), the semiconductor chip, and the molding material (epoxy molding compound: EMC) at the time of hardening the semiconductor chip.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A semiconductor chip package comprising:
a printed circuit board (PCB) forming a base of the package;
a semiconductor chip mounted on the PCB;
a molding part molding the entire upper surface of the PCB including the semiconductor chip to protect the semiconductor chip from external environment; and
a warpage suppressing reinforcement member bonded to an upper surface of the molding part and suppressing warpage of the package generated due to a difference in a thermal expansion coefficient among the PCB, the semiconductor chip, and a molding material at the time of hardening the molding material of the molding part.

2. The semiconductor chip package according to claim 1, wherein the molding material of the molding part is a thermosetting resin.

3. The semiconductor chip package according to claim 2, wherein the thermosetting resin is any one of an epoxy resin, a phenol resin, a urea resin, a melamine resin, an unsaturated polyester resin, a polyurethane resin, and a polyimide resin.

4. The semiconductor chip package according to claim 1, wherein the warpage suppressing reinforcement member is made of a material having high rigidity and a low thermal expansion coefficient.

5. The semiconductor chip package according to claim 4, wherein the warpage suppressing reinforcement member is made of a carbon fiber composite material or a metal material.

6. The semiconductor chip package according to claim 1, wherein the warpage suppressing reinforcement member has any one of a sheet shape, a cross shape, and a net (lattice) shape.

7. A manufacturing method of a semiconductor chip package, the manufacturing method comprising:
mounting a semiconductor chip on a printed circuit board (PCB);
inserting a warpage suppressing reinforcement member into an inner ceiling of a mold manufactured in order to package the PCB having the semiconductor chip mounted thereon;
combining the mold having the warpage suppressing reinforcement member inserted into the ceiling thereof with the upper surface of the PCB so as to surround the PCB having the semiconductor chip mounted thereon;
injection-molding and filling a molding material in the mold and hardening the molding material by applying heat, and
hardening the molding material and then removing the mold to complete the semiconductor chip package.

8. The manufacturing method of claim 7, wherein in the inserting, the warpage suppressing reinforcement member is made of a material having high rigidity and a low thermal expansion coefficient.

9. The manufacturing method of claim 8, wherein the warpage suppressing reinforcement member is made of a carbon fiber composite material or a metal material.

10. The manufacturing method of claim 7, wherein the warpage suppressing reinforcement member has any one of a sheet shape, a cross shape, and a net (lattice) shape.

11. The manufacturing method of claim 7, wherein in the injection-molding and filling, the molding material is a thermosetting resin.

12. The manufacturing method of claim 11, wherein the thermosetting resin is any one of an epoxy resin, a phenol resin, a urea resin, a melamine resin, an unsaturated polyester resin, a polyurethane resin, and a polyimide resin.
